(19) United States
(12) Patent Application Publication
(10) Pub. No.: US 2008/0290355 A1
(43) Pub. Date: Nov. 27, 2008

(54) Warm white LED and its phosphor that provides orange-yellow radiation

(76) Inventors: Soshchin Naum, Changhua City (TW); Wei-Hung Lo, Taipei City (TW); Chi-Ruei Tsai, Taipei City (TW)

Correspondence Address: TROXELL LAW OFFICE PLLC;ONE SKYLINE PLACE, SUITE 1404, 5205 LEESBURG PIKE, FALLS CHURCH, VA, 22041, US

(21) Appl. No.: 12/005,425

(22) Filed: Dec. 27, 2007

(30) Foreign Application Priority Data
Dec. 28, 2006 (TW) 095149453

(51) Int. Cl. H01L 33/00; C09K 11/08

(52) U.S. Cl. 257/94; 252/301.4 R; 257/E33.001

(57) ABSTRACT

A phosphor providing orange-yellow radiation for use in warm white LEDs (light emitting diodes) is disclosed to include a substrate prepared from a rear-earth garnet and an activating agent prepared from cerium. The phosphor has a constant radiation maximum value under excitement of InGaN, and the total chemical stoichiometric equation of the phosphor substrate is (ΣLn)₃Al₅O₁₂, in which ΣLn=Y_{1-x-y-z-p}GdₓLu_{y}Yb⁺³_{z}Eu⁺³ₚ. The activating agent can be Ce (Cerium), Pr (Praseodymium), Dy (Dysprosium), Er (Erbium), or Sm (Samarium). In InGaN LED application, the phosphor assures high radiation strength and high optical output efficiency within 50˜80 lm/w. The invention also discloses a warm white LED using the phosphor.

### BACKGROUND OF THE INVENTION

1. Field of the Invention

The present invention relates to light emitting technology and more particularly, to a warm white LED based on an InGaN semiconductor heterostructure and the phosphor which using cerium as the activating agent that, under the activation of the shortwave of InGaN.

2. Description of the Related Art

Following progress of semiconductor technology, semiconductor illumination technology (“solid light source”) has been developed rapidly. The fast development in this field should be attributed to the technical achievement of the pioneer, i.e., InGaN shortwave semiconductor LED from Suji Nakamura of Nichia Chemical, Japan, (see S. Nakamura “The Blue laser diodes”, Berlin, Springer 1997).

By means of the combination of a semiconductor heterostructure (P-N junction) and a phosphor, white light radiation is obtained. White light produced by means of the radiation conversion of a phosphor from Ultraviolet, violet and blue LEDs is in conformity with Stokes' Law (see A Berg, P Din. LED. N-Y, Pergamon press, 1975 and B.A.A [symbol] paMOB. AB [symbol] OpCKOe CB [symbol] e [symbol] e [symbol] C [symbol] BO CCCP N635813, [symbol] p [symbol] op [symbol] Sep. 12, 1977).

During 1997˜1998, high brightness white LED was successfully created. It uses a phosphor prepared from a substrate based on Y₃Al₅O₁₂:Ce (see G Blasse Luminescence material. Berlin, Springer, 1994) that was earlierly used in professional electronic radiography. In an early design of white LED, the yellow light radiated by the garnet phosphor is combined with the blue light radiated by the LED, thereby producing cold white light.

Further, prior art patents have the basic drawback. The invention has referred to prior art patents, and make use of them. Same as the drawback of the cold white radiation, conventional LEDs and their phosphor YAG:Ce have other drawbacks: 1. Low quantum radiation output; 2: Low total luminance efficiency; and 3: Low stability during working.

To eliminate the aforesaid substantial drawbacks, a specific phosphor is developed to assure more warm color tone in white LED radiation. This composition has added thereto gadolinium ions (Gd⁺³).

As well known, a solid solution compound is formed between gadolinium and yttrium in YAG, having the concentration of: Gd about 50% atomic units. Under this condition, the border width of (Y,Gd)₃Al₅O₁₂ is reduced, and the radiation energy level of the activating agent Ce⁺³ is lowered. The radiation occurs only at the lower-energy level. Therefore, the major radiation of the phosphor is shifted to orange light.

There are some other companies who developed warm white LEDs using a covering prepared from the phosphor that uses the solid solution compound between gadolinium and yttrium as the substrate and cerium as the activating agent. Identification experiment of this phosphor has about 5 years. However, a series of drawbacks can still be found: 1. The wavelength variation of spectrum maximum value is determined subject to the temperature during working of the LED 2. Drastical reducing of luminance brightness during heating of the phosphor (“temperature quenching”); and 3. Color varies with change of temperature condition during working of the LED.

Further, the market phosphors, either cold white color or warm white color, commonly the durability to be no good. For example, the luminance brightness of white light LED with InGaN chip and YAG phosphor is reduced by 15˜20% after a first 1000 hours in a continuous working.

Therefore, it is desirable to provide a warm white LED and the related phosphor with orange-yellow radiation that does not reduce its luminance brightness and change its colority after long working.

### SUMMARY OF THE INVENTION

The present invention has been accomplished a LED and its phosphor that eliminates the aforesaid problems. It is therefore the main object of the present invention to provide a warm white LED and its phosphor, which has Ce⁺³ related supplements added to the phosphor for controlling the type of the spectrum curve of the radiation of the phosphor. It is another object of the present invention to provide a warm white LED and its phosphor, which has 5 relative extremes after the wavelength surpassed the extreme, and the values of these 5 relative extremes can be accurately measured on the transverse axis.

To achieve these and other objects, the phosphor providing orange-yellow radiation for use in warm white LEDs (light emitting diodes) comprises a substrate prepared from a rear-earth garnet and an activating agent prepared from cerium, wherein the phosphor has a constant radiation maximum value under excitement of InGaN, and the total chemical stoichiometric equation of the phosphor substrate is (ΣLn)₃Al₅O₁₂, in which ΣLn=Y_{1-x-y-z-p}GdₓLu_{y}Yb⁺³_{z}Eu⁺³ₚ; activating agent is selected from Ce (Cerium), Pr (Praseodymium), Dy (Dysprosium), Er (Erbium), or Sm (Samarium).

To achieve these and other objects of the present invention, the warm white LED comprises a substrate prepared from an InGaN semiconductor heterostructure, and a phosphor layer covering the radiating surface and rhombic faces of the InGaN semiconductor heterostructure. The phosphor layer is as stated above. The total white light radiation of the LED is obtained from mixing of the luminance of said phosphor and the blue radiation of the InGaN semiconductor heterostructure, and has a color temperature T=2800-4300 k.

Further, the constant radiation maximum value is λ=567.8±5 nm and the half wave width is λ_{0.5}=16.3˜124 nm. The activating agent is selected in priority from the elements having oxidation degree +3, including Ce⁺³, Pr⁺³, Sm⁺³, Dy⁺³ or Er⁺³.

Further, the rare-earth substrate that composes the lattiis prepared from ΣLn=Y_{1-x-y-z-p}GdₓLu_{y}Yb⁺³_{z}Eu⁺³ₚ, having a concentration: 0.001≦X≦0.1, 0.000≦Y≦0.02, 0.000≦Z≦0.001, 0.000≦P≦0.05, and the total concentration of said activating agent in the anions of the phosphor substrate does not exceed by Σactivation=[Ce⁺³+Pr⁺³+Sm⁺³+Dy⁺³+Er⁺³]=0.05 atomic fraction.

Further, the best optimal content of Gd⁺³ in the substrate is within 0.01≦[Gd]≦0.03 atomic fraction; the best optimal content of Lu⁺³ in the substrate is within 0.005≦[Lu]≦0.01 atomic fraction.

Further, the best optimal content of Ce⁺³ is within 0.02≦[Ce⁺³]≦0.04; the content of the second activating agent Sm⁺² is within 0.005≦[Sm⁺³]≦0.01; at least 50% of the Sm ions is at oxidation degree +3.

Further, when constantly excited, the spectrum curve of the phosphor has 5 relative extremes at the wavelength when passed over the maximum wavelength value, and the strength at this wavelength is 0.5˜10% higher than the radiation strength of the major activating agent Ce⁺³.

Further, the wavelength of the radiation spectrum of the phosphor is variable by short and ultrashort optical pulse where the pulse lasting time is τ=11 μs˜1 ms.

Further, the spectrum lumen equivalent of the phosphor is 240≦Q_{L}≦300 lm/w.

Further, when the composition of the phosphor is (Y_{0.9349}Gd_{0.03}Lu_{0.005}Yb_{0.0001}Ce_{0.025}Sm_{0.005})₃Al₅O₁₂, the radiation color coordinates is x=0.385 y=0.45, and the color purity is increased by 0.06.

Further, when the composition of the phosphor is (Y_{0.94}Gd_{0.01}Lu_{0.005}Yb_{0.0001}Ce_{0.029}Sm_{0.0159})₃Al₅O₁₂, the color coordinates of the radiation is x>0.40 y>0.47, and the color purity is >0.63.

Further, the phosphor has an average diameter 2≦d_{cp}≦4 μm.

### DETAILED DESCRIPTION OF THE PREFERRED EMBODIMENT

The main object of the present invention is to eliminate the drawback of YAG (yttrium aluminum garnet) phosphor. To achieve this object, the invention provides a phosphor providing orange-yellow radiation for use in warm white LED. The phosphor providing orange-yellow radiation uses rare-earth garnet as the substrate and cerium as the activating agent. The invention is characterized in that the phosphor has the constant radiation of the maximum value under InGaN shortwave activation; the total stoichiometric equation of the phosphor substrate is: (ΣLn)₃Al₅O₁₂, in which ΣLn=Y_{1-x-y-z-p}GdₓLu_{y}Yb⁺³Eu⁺³ₚ, and the activating agent can be Ce (Cerium), Pr (Praseodymium), Dy (Dysprosium), Er (Erbium), or Sm (Samarium).

The physical chemistry principle of the composition of the phosphor of the present invention is outlined hereinafter. At first, the substrate of the anions in crystal lattice is composed of Yttrium ions, Gadolinium ions, Lutetium ions, Ytterbium ions and Europium ions, each having a specific effect. Using yttrium ions as the major composition is for the advantages of its proper ion radius, τ_{Y}=0.97 A, and its high coordination number K=12. Because of these features, Yttrium ions can substitute for rare-earth irons to form a strong crystal lattice for the phosphor substrate. Gadolinium ions are intensively used in ingredients for garnet phosphor as for optical displacement of radiation band of cerium irons (Ce⁺³). However, the following description will indicate that the concentration of gadolinium ions (Gd⁺³) will be substantially reduced. As stated above, when a big amount of Gadolinium atoms exists in the crystal lattice, the luminous intensity of cerium irons (Ce⁺³) will be reduced subject to increasing of temperature. Therefore, we can reduce this phenomenon by reducing the content of gadolinium eliminates. Further, two smallest rare-earth irons such as Lu⁺³, τ_{Lu}=0.83 A and Yb⁺³, τ_{Yb}=0.81 A are used in the ingredients, assuring reduced crystalline electric field gradient of the garnet substrate, exciting various Ce⁺³ radiations.

When Lu⁺³ is added to garnet crystal lattice ions, Ce⁺³ excites spectrum to displace to a shortwave of wavelength λₘₐₓ=460˜440 nm. Further, the added Lu⁺³ increases the luminous brightness of the phosphor. It is for sure that when the atomic fraction of Lu⁺³ ions in the phosphor substrate is increased to 1%, the brightness is increased by 1.25˜1.5%. Adding two different extent of oxidation of ytterbium, even at a small amount, can regulate the value of important parameters the phosphor, for example, afterglow time.

Erbium ions can be in garnet crystal lattice in two different extent of oxidation, Eu⁺³ and Eu⁺². Eu⁺³ shows a weak luminous characteristic, however its luminance is fully absorbed by Ce⁺³ ions, and existence of Eu⁺² assures strong absorption of excited light.

The color of the phosphor is close to bright yellow. Its reflective coefficient becomes R≧75% in the area λ>560 nm. Therefore, the new composition of the phosphor substrate of the present invention contain the ions Y⁺³, Gd⁺³ and Lu⁺³ of which the oxidation is constant and the ions of Eu⁺², Eu⁺³, Yb⁺² and Yb⁺³ of which the oxidation is variable. According to the present inventor's opinion, this substrate composition has never been used. This new composition of phosphor assures a series of excellent optical performances: 1. Strong absorption of heterostructure blue light primary radiation; 2. High luminous quantum output; 3. Insignificant influence of heat on radiation; and 4. Nonvariability of the maximum value and halfwidth of the spectrum.

The phosphor of the present invention has the features that the rare-earth elements that compose the substrate of the phosphor are obtained from ΣLn=Y_{1-x-y-z-p}GdₓLu_{y}Yb_{z}Euₚ series, of which the concentration is: 0.001≦X≦0.1, 0.000≦Y≦0.02, 0.000≦Z≦0.001, 0.000≦P≦0.05. Under this condition, the total concentration of the anions of the activating agent doped compound in the phosphor substrate does not exceed by ΣTR⁺³=[Ce⁺³+Pr⁺³+Sm⁺³+Dy⁺³+Er⁺³]=0.05 atomic fraction.

The relationship of the quantity ratio of the elements that compose the phosphor according to the present invention allows precision fabrication of the phosphor. To reliably obtain the material having the assigned properties, the phosphor has the features: the range of the most optimal content of Gd⁺³ in the phosphor substrate is within 0.01≦[Gd]≦0.03 atomic fraction, and the range of the most optimal content of Lu⁺³ in the phosphor substrate is within 0.005≦[Lu]≦0.01 atomic fraction.

When compared to the concentration of the garnet substrate in a standard phosphor, the aforesaid quality is substantially reduced (usually 30% gadolinium and 5% lutetium in a standard phosphor). Reducing the concentration of similar basic ingredients substantially lowers the cost.

The material composition of the present invention is not limited to the aforesaid advantage. A disclosed phosphor having the same composition is characterized by: the major activating agent compound has the most optimal content. Specifically speaking, the range of cerium ion content in phosphor substrate is within 0.02≦[Ce⁺³]≦0.04, the range of samarium ion content is 0.005≦[Sm]≦0.01, and the range of the other activating agent content are: 0.001≦[Pr⁺³]≦0.003, 0.0005≦[Dy⁺³]≦0.005 and 0.0005≦[Er⁺³]≦0.0005. In a phosphor composition, at least two basic activating agents are contained, i.e., Ce⁺³ and Sm⁺³. The existence of the other three activating agents is subject to the purpose of the phosphor in the LED. When emphasizing yellow radiation of the phosphor, Er⁺³ shall be added to the phosphor. When considering concentration of radiation of the maximum value of the spectrum of the phosphor, Dy⁺³ may be added. For the sake of amplification of the secondary radiation, Pr⁺³ may be added.

The most important feature of the phosphor according to the present invention is: adding Ce⁺³ related supplements to the phosphor controls the type of the spectrum curve of the radiation of the phosphor. The tupe of the spectrum is one of its features.

Further, the main difference of the phosphor of the present invention is its unusual spectrum type. Gaussian curve is a symmetrical curve representing the normal distribution, i.e., the curves show symmetrical on the transverse axis at two sides of the perpendicular axis of the maximum value of the spectrum. Unlike Gaussian curve, the phosphor of the present invention has an asymmetrical axial curve. There are two relative extremes in the curve. The wavelength is about λ=545.8˜567.8 nm. There is a recess between the extremes. The radiation strength is about 5% below the maximum value.

The spectrum of the phosphor of the present invention has another feature: when the wavelength surpassed the extreme, there are another 5 relative extremes, and their values can be accurately measured on the transverse axis. Table 1 shows comparison between the Standard YAG:Ce and the disclosed phosphor of the present invention.

TABLE I

| | | Phosphor of the | Standard |
|---|---|---|---|
| No | Parameter | invention | YAG:Ce |
| 1 | Type of spectrum | Curve with two slopes | Gaussian curve |
| | curve | | |
| 2 | Maximum valueof | 2 relative maximum | One spectrum |
| | spectrum | values, 5 relative | maximum value |
| | | extremes of relatively | |
| | | smaller value | |
| 3 | Discrimination of | No | Yes, pass through |
| | symmetric axis | | the point between |
| | | | the extreme and the |
| | | | transverse axis |
| 3′ | Discrimination of | L/Δγ~250 | ~200 |
| | concentratability | | |
| | of radiation energy | | |
| 4 | Spectrum curve | Medium width | Width |
| | halfwave width | Δ = 114~118_{HM} | Δ = 129.1_{HM} |
| 5 | Color purity of | 0.5966-0.7220 | 0.5843 |
| | given spectrum | | |
| 6 | Sum of Color | 0.84~0.88 | 0.84 |
| | coordinates | | |
| 7 | Warm red light frac- | 1% | 5% |
| | tion in spectrum | | |

From the indication of Table 1, the type of the basic spectrum of the phosphor of the present invention is quite different from that of the known YAG:Ce composition. The following description will explain that the aforesaid discriminations are not the exclusive. Multicolor or chromatographic phenomenon is seen in the phosphor of the present invention. When constantly excited, the spectrum of the phosphor is as stated above. However, when excited with a narrow pulse for a period Σ=5 ms, a variation of visible spectrum occurs, i.e., the spectrum is narrowed.

In white LEDs, green radiation of the phosphor can sometimes be observed, i.e., the radiation of the orange sub-energy band is weakened. This phenomenon is insignificant in the application of LEDs for illumination. However, it is important in the field of building industry or advertising industry for creating a color effect.

Using a heterostructure to change the pulse time of the luminance of a phosphor can change the colority of the radiation of the light source. The application of similar attributes of phosphor in white LEDs has not yet been seen. The calculation is to make sure of the lumen equivalent value of the radiation of the disclosed phosphor. With respect to the composition of the present invention shown in Annex I, the lumen equivalent value is Q_{L}=250 lm/w. At first, it is determined subject to the wavelength displacement of the right-wing of the spectrum of the radiation of the material. This material reaches Ra (general color rendering index) chromatic value, and Ra (general color rendering index) has the maximum value in orange-red zone. Annex II is a phosphor spectrum diagram, showing the concentration variation of key ingredients. Under this condition, because of displacement toward yellow spectrum (λ=545.8 nm), the lumen equivalent value of the phosphor increases substantially to Q_{L}=290 lm/w. When increasing the concentration of certain doped ions in the phosphor such as Lu⁺, a second spectrum maximum value λ=545.8 nm will appear. Similar phosphors have a high lumen equivalent value (see Annex II), and the value is Q_{L}>=300 lm/w.

Further, the phosphor of the present invention has another special characteristic, i.e., it shows high color purity. This is more important in orange and red spectrums. In this zone, the radiation of the phosphor has a high color purity value>0.60, and a chromatic coordinate value x=0.309, y=0.45 (Y_{0.9}Gd_{0.03}Lu_{0.0199}Yb_{0.0001}Ce_{0.025}Sm_{0.005})₃Al₅O₁₂. In another chemical composition of phosphor (Y_{0.93}Gd_{0.01}Lu_{0.0099}Yb_{0.0001}Ce_{0.025}Sm_{0.005})₃Al₅O₁₂, the purity of orange-yellow radiation is >0.63, and the total color coordinate value is as high as Σx+y≧0.90. The application of these high color purity phosphors in the fabrication of warm white LEDs is not seen in literature.

The important feature of the phosphor according to the present invention is its dispersion composition. Powder diameter of phosphor for white LED gives rise to disputes in many patent document. In early patent documents, it is acknowledged that fine dispersion powder assures formation of a covering substance on the surface of the semiconductor heterostructure and radiating prisms. However, a white LED made in this way is soon proved that very fine dispersion phosphor does not provide high luminance brightness. The suggestion of simply using granular phosphor is also not practical because its application cannot provide white light. According to the data of the present invention, eliminates the aforesaid complicated problem requires a moderately dispersed phosphor of which the maximum size is 10 μm.

However, to ensure high radiation capability, these powders shall be presented in a clear prism configuration, i.e., having natural lateral edges and a crystal shape. It can be found in natural compound minerals for composing a phosphor substrate. The initially obtained phosphor according to the present invention shows a hexagonal dodecahedron shape, i.e., 12 rhomic faces each having the shape of a normal hexagon.

There is a requirement for the phosphor, i.e., high transmittancy at radiation spectrum. With respect to dispersion preparation, a laser diffractometer is used, assuring dimensional precision of the powder to be 0.1 μm. The transmittance of the powder is examined in a microtelevision system. The measuring result of the dispersed composition is shown in Annex III. The frequency distributor indicates the distribution of the powder. The diameter and surface area data is shown in the table. The best optimal powder diameter is 2 μm<d_{cp}≦4 μm.

Table II shows the related data of various samples of the orange-yellow phosphor. From the data shown in the table, it is apparent that the color coordinates of the proposed phosphor will change within the interval value: x=0.38+0.02 and y=0.46+0.02, i.e., the change is insignificant. The radiation of the phosphor always carries orange-yellow color. It can be well mixed with the blue and light blue radiation of the semiconductor heterostructure to form the desired warm white color for illumination.

TABLE II

| | | | Color | | |
|---|---|---|---|---|---|
| | | | coordinates | | |
| No | Basic composition of phosphor | Composition of activation compound | x y | Brightness | Q_{L}value |
| 1 | (Y_{0.924}Gd_{0.03}Lu_{0.005}Yb_{0.0001}Eu_{0.005})₃Al₅O₁₂ | Ce_{0.025}Pr_{0.002}Sm_{0.005}Dy_{0.0039} | 0.385 | 30050 | 295 |
| | | | 0.452 | | |
| 2 | (Y_{0.939}Gd_{0.01}Lu_{0.01}Yb_{0.0001})₃Al₅O₁₂ | Sm_{0.01}Ce_{0.03}Pr_{0.005}Er_{0.004} | 0.4015 | 27960 | 255 |
| | | | 0.4698 | | |
| 3 | (Y_{0.85}Gd_{0.088}Lu_{0.01}Yb_{0.002})₃Al₅O₁₂ | Ce_{0.03}Sm_{0.015}Pr_{0.002}Dy_{0.001}Er_{0.002} | 0.4280 | 28720 | 300 |
| | | | 0.4682 | | |
| 4 | (Y_{0.96}Lu_{0.01}Eu_{0.013})₃Al₅O₁₂ | Ce_{0.01}Dy_{0.001}Sm_{0.005}Er_{0.001} | 0.396 | 29790 | 295 |
| | | | 0.4722 | | |
| 5 | (Y_{0.96}Gd_{0.01}Eu_{0.012})₃Al₅O₁₂ | Ce_{0.01}Dy_{0.001}Sm_{0.005}Er_{0.001}Pr_{0.001} | 0.4112 | 31000 | 305 |
| | | | 0.4696 | | |
| 6 | (Y_{0.96}Eu_{0.01}Yb_{0.0001})₃Al₅O₁₂ | Ce_{0.02}Er_{0.001}Sm_{0.01} | 0.4076 | 30750 | 300 |
| | | | 0.4702 | | |
| 7 | (Y_{0.9}Gd_{0.01}Lu_{0.02}Yb_{0.001}Eu_{0.02})₃Al₅O₁₂ | Ce_{0.02}Er_{0.005}Sm_{0.02}Pr_{0.004} | 0.4096 | 29790 | 295 |
| | | | 0.4708 | | |
| 8 | (Y_{0.93}Gd_{0.01}Lu_{0.01}Yb_{0.001}Eu_{0.01})₃Al₅O₁₂ | Ce_{0.005}Er_{0.004}Sm_{0.025}Pr_{0.004}Dy_{0.001} | 0.4104 | 30100 | 260 |
| | | | 0.4692 | | |
| 9 | (Y, Gd, Ce)₃Al₅O₁₂ | — | 0.364 | 28600 | 280 |
| | standard | | 0.394 | | |

The invention also discloses a warm white LED that comprises a substrate prepared from an InGaN semiconductor heterostructure. The InGaN semiconductor heterostructure has its radiating surface covered with a phosphor layer. The composition of the phosphor of the phosphor layer is prepared subject to the previous description, and characterized in that the total white light radiation of the LED comes from mixing of the luminance of the phosphor with the blue radiation of the InGaN semiconductor heterostructure, having a color temperature T=2800˜4300 K.

The stability of optical technique parameters during continuos working is the most important parameter of the warm white LED. In some patents, the light intensity and optical flux will be reduced after 1000 hours. According to the data of the present invention, similar rapid variation has a great concern with destruction of the optical contact between the phosphor and the polymer adhesive. The phosphor of the present invention shows no any defect in a long test. It is for sure that the use of the phosphor of the present invention in a warm white LED can increase the intensity of the initial light by 4˜16%. A LED having this special performance is subject to the use of a high quality phosphor.

In conclusion, the warm white LED of the present invention is constrained by temperature when the brightness, colority and optical maximum value are reduced. Further, the phosphor providing orange-yellow radiation does not reduces its brightness after a long time test. Therefore, the phosphor of the present invention improves the drawbacks of the conventional YAG florescent powder.

Although a particular embodiment of the invention has been described in detail for purposes of illustration, various modifications and enhancements may be made without departing from the spirit and scope of the invention.

What is claimed is:

1. A phosphor providing orange-yellow radiation for use in warm white LEDs (light emitting diodes), the phosphor comprising a substrate prepared from a rear-earth garnet and an activating agent prepared from cerium, wherein the phosphor has a constant radiation maximum value under excitement of InGaN, and the total chemical stoichiometric equation of the phosphor substrate is (ΣLn)₃Al₅O₁₂, in which ΣLn=Y_{1-x-y-z-p}GdₓLu_{y}Yb⁺³_{z}Eu⁺³ₚ; activating agent is selected from Ce (Cerium), Pr (Praseodymium), Dy (Dysprosium), Er (Erbium), or Sm (Samarium).

2. The phosphor as claimed in claim 1, wherein said constant radiation maximum value is λ=567.8±5 nm and the half wave width is λ_{0.5}=116.3˜124 nm.

3. The phosphor as claimed in claim 1, wherein said activating agent is selected in priority from the elements having oxidation degree +3, including Ce⁺³, Pr⁺³, Sm⁺³, Dy⁺³ or Er⁺³.

4. The phosphor as claimed in claim 1, wherein said rare-earth substrate is prepared from ΣLn=Y_{1-x-y-z-p}GdₓLu_{y}Yb⁺³_{z}Eu⁺³ₚ, having a concentration 0.001≦X≦0.1, 0.000≦Y≦0.02, 0.000≦Z≦0.001, 0.000≦P≦0.05.

5. The phosphor as claimed in claim 1, wherein the total concentration of said activating agent in the anions of the phosphor substrate does not exceed by Σactivation=[Ce⁺³+Pr⁺³+Sm⁺³+Dy⁺³+Er⁺³]=0.05 atomic fraction.

6. The phosphor as claimed in claim 1, wherein the best optimal content of Gd⁺³ in the substrate is within 0.01≦[Gd]≦0.03 atomic fraction; the best optimal content of Lu⁺³ in the substrate is within 0.005≦[Lu]≦0.01 atomic fraction.

7. The phosphor as claimed in claim 1, wherein the best optimal content of Ce⁺³ is within 0.02≦[Ce⁺³]≦0.04; the content of the second activating agent Sm⁺² is within 0.005≦[Sm⁺³]≦0.01; at least 50% of the Sm ions is at oxidation degree +3.

8. The phosphor as claimed in claim 1, wherein when constantly excited, the spectrum curve of the phosphor has 5 relative extremes at the wavelength over the maximum wavelength value, and the strength at this wavelength is 0.5˜10% higher than the radiation strength of the major activating agent Ce⁺³.

9. The phosphor as claimed in claim 1, wherein the wavelength of the radiation spectrum of the phosphor is variable by short and ultrashort optical pulse where the pulse lasting time is τ=11 μs˜1 ms.

10. The phosphor as claimed in claim 1, wherein the spectrum lumen equivalent of the phosphor is 240≦Q_{L}≦300 lm/w.

11. The phosphor as claimed in claim 1, wherein when the composition of the phosphor is (Y_{0.9349}Gd_{0.03}Lu_{0.005}Yb_{0.0001}Ce_{0.025}Sm_{0.005})₃Al₅O₁₂, the radiation color coordinates is x=0.385 y=0.45, and the color purity is increased by 0.06.

12. The phosphor as claimed in claim 1, wherein when the composition of the phosphor is (Y_{0.94}Gd_{0.01}Lu_{0.005}Yb_{0.0001}Ce_{0.029}Sm_{0.0159})₃Al₅O₁₂, the color coordinates of the radiation is x>0.40 y>0.47, and the color purity is >0.63.

13. The phosphor as claimed in claim 1, wherein the phosphor has an average diameter 2≦d_{cp}≦4 μm.

14. A warm white LED (light emitting diode), comprising a substrate prepared from an InGaN semiconductor heterostructure and a phosphor layer covering radiating surface and rhombic faces of said InGaN semiconductor heterostructure, said phosphor layer comprising a phosphor prepared according to claim 1, wherein the total white light radiation of the LED is obtained from mixing of the luminance of said phosphor and the blue radiation of said InGaN semiconductor heterostructure and has a color temperature T=2800˜4300 k.
